(19) United States
(12) Patent Application Publication
(10) Pub. No.: US 2008/0108214 A1
(43) Pub. Date: May 8, 2008

(54) Threshold voltage targeting in carbon nanotube devices and structures formed thereby

(75) Inventors: Amlan Majumdar, Portland, OR (US); Robert S. Chau, Beaverton, OR (US); Justin K. Brask, Portland, OR (US); Marko Radosavljevic, Beaverton, OR (US); Matthew V. Metz, Hillsboro, OR (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/299,228

(22) Filed: Dec. 9, 2005

(51) Int. Cl. H01L 21/44

(52) U.S. Cl. 438/597

(57) ABSTRACT

Methods and associated structures of forming a microelectronic device are described. Those methods may include forming at least one metal source/drain on a gate dielectric, wherein the at least one metal source/drain is adjacent to a channel region, wherein the channel region comprises at least one carbon nanotube.

### BACKGROUND OF THE INVENTION

Single walled carbon nanotubes (CNTs) may posses semiconducting or metallic properties depending upon the chirality of the CNT. Semiconducting CNTs with 1-2 nm diameters may exhibit energy bandgaps within a range of about 0.8 to about 0.4 electron volts. Both electrons and holes are expected to have good transport properties within CNTs, consequently semiconducting CNTs appear as attractive candidates for use as channels within field-effect transistors (FETs), for example.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1e represent structures according to an embodiment of the present invention.

FIG. 2 represents a graph according to an embodiment of the present invention.

FIG. 3 represents a graph according to an embodiment of the present invention.

FIG. 4. represents a system according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may comprise forming at least one metal source/drain on a gate dielectric, wherein the at least one metal source/drain is adjacent to a channel region, and wherein the channel region comprises at least one CNT. Methods of the present invention may enable the targeting of a desired threshold voltage of a CNT device, such as a CNT FET device, for example.

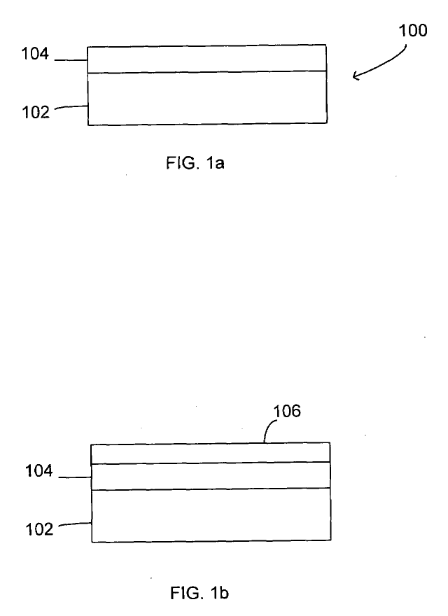

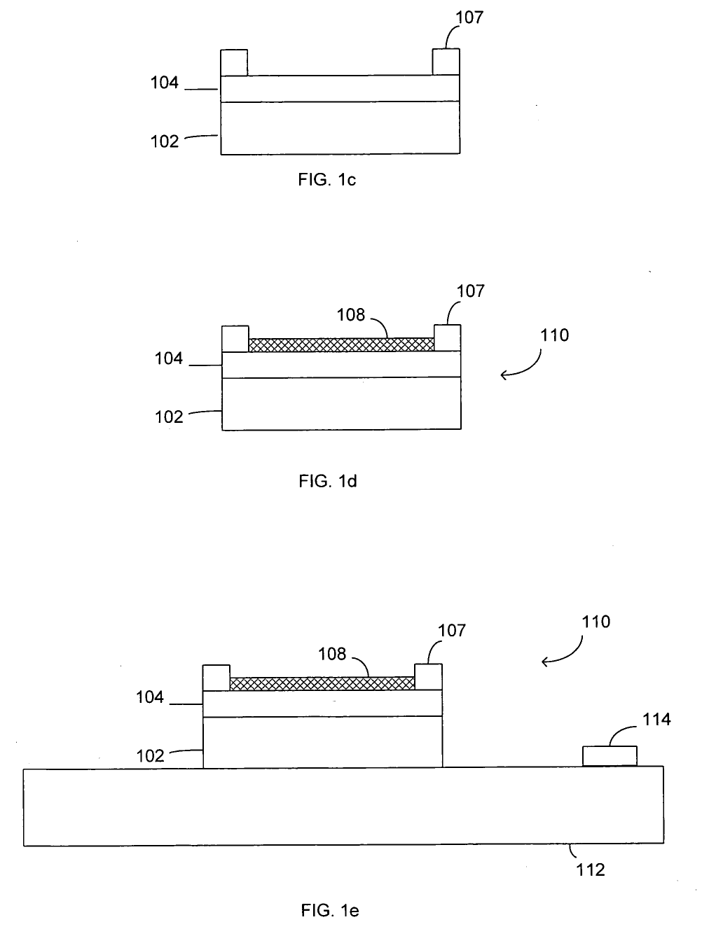

FIGS. 1a-1e illustrate an embodiment of a method of forming a microelectronic structure, such as a CNT FET structure, for example. FIG. 1a illustrates a cross-section of a portion of a substrate 100. The substrate 100 may be comprised of materials such as, but not limited to, silicon, silicon-on-insulator, germanium, indium antimonide, lead telluride, indium arsenide, indium phosphide, gallium arsenide, gallium antimonide, or combinations thereof. In one embodiment, the substrate 100 may be doped with p-type dopant, as are well known in the art.

In one embodiment, the substrate 100 may be doped with any p-type of dopant, as are well known in the art. In one embodiment, the substrate 100 may comprise a p+ backside gate 102 of a FET device, for example. In one embodiment, the p+ backside gate 102 may be silicon heavily doped with a p-type dopant, such as boron, for example, as is well known in the art.

The substrate 100 may further comprise a gate dielectric 104. The gate dielectric 104 may comprise a silicon dioxide layer or high k gate dielectric material, in some embodiments. In one embodiment, the gate dielectric 104 may comprise metal oxides such as hafnium oxide and/or lanthanum oxide, for example. In other embodiments, the materials that may comprise the gate dielectric 104 may include zirconium oxide, titanium oxide, and aluminum oxide. Although a few examples of materials that may be used to form the gate dielectric 104 are described here, that layer may be made from other materials that may serve to reduce gate leakage. In one embodiment, the gate dielectric 104 may have a thickness from about 10 Angstroms to about 150 Angstroms. In one embodiment, the gate dielectric 104 may comprise a dielectric material comprising a dielectric constant greater than about 10.

A conductive material 106 may be formed on the gate dielectric 104 (FIG. 1b). In one embodiment, the conductive material 106 may comprise various metallic materials. In one embodiment, the conductive material 106 may comprise a at least one of palladium and tungsten, and combinations thereof. In one embodiment, the conductive material 106 may be formed using PVD (“Physical vapor deposition”), CVD (“Chemical vapor deposition”), or ALD (“Atomic Layer deposition”) as are known in the art. In one embodiment, the conductive material 106 may comprise a thickness from about 500 to about 2,000 angstroms.

In one embodiment, the composition of the conductive material 106 may be chosen to comprise a targeted work function for a desired device, such as for a CNT FET device, for example. Thus, by selecting the composition and thus the work function of the conductive material 106, a desired threshold voltage may be engineered, set, targeted, and/or adjusted depending upon the particular application and/or device.

In one embodiment, the conductive material 106 may comprise a suitable work function value that is compatible with a PMOS gate device (which may comprises a work function value of about 5.1+/−0.5 electron volts). In another embodiment, the conductive material 106 may comprise a suitable work function value that is compatible with an NMOS gate device (which may comprises a work function value of about 4.1+/−0.5 electron volts). In one embodiment, the conductive material 106 may be patterned to form at least one metal source/drain 107 (FIG. 1c). The at least one metal source/drain region 107 may be patterned using any suitable patterning technique, such as lithographic techniques, for example.

In one embodiment, at least one carbon nanotube (CNT) 108 may be placed and/or formed on the gate dielectric 104 (FIG. 1d). In one embodiment, the at least one CNT 108 may be disposed between a metal source/drain 107 pair, and may be attached and/or electrically coupled between a metal source/drain 107 pair. In one embodiment, the at least one CNT 108 may be placed and/or formed from solution, for example, using Langmuir-Blodgett or self-assembly-techniques. In another embodiment, the at least one CNT 108 may be directly grown on the gate dielectric 104 over the substrate 100 by utilizing a chemical vapor deposition (CVD) process, for example. In some embodiments, the at least one CNT 108 may comprise at least one single walled CNT, and may comprise at least one semiconducting CNT.

It will be understood by those skilled in the art that the at least one source/drain region 107 may be formed subsequent to the formation and/or placing of the at least one CNT 108 on the gate dielectric 104, depending upon the particular application. In one embodiment, the at least one CNT 108 may form a channel region of a CNT structure 110, such as a CNT FET device structure, for example. In one embodiment, by selecting the composition and thus the work function of the at least one metal source/drain 107 of the CNT structure 110, a desired threshold voltage of the CNT structure 110 may be engineered, set, targeted, and/or adjusted, depending upon the particular application. The CNT structure 110 may further be coupled and/or attached to a second substrate 112, such as but not limited to a motherboard, an interposer or a package and combinations thereof (FIG. 1e). The second substrate 112 may comprise a memory device 114, as are well known in the art.

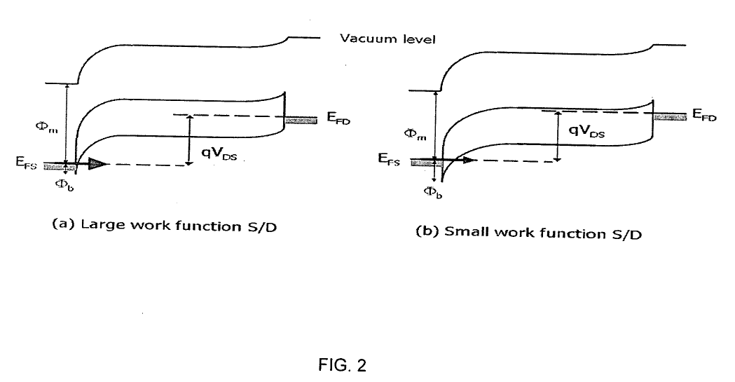

FIG. 2 depicts an energy band diagram of an exemplary CNT FET that may comprise at least one metal source/drain, such as the CNT FET of FIG. 1d, for example. Φₘ is the metal source/drain work function. Φ_{b} is the Schottky barrier height at the metal-CNT interface. V_{DS} is the applied drain-source bias, and E_{FS} and E_{FD} are the Fermi level in the source and drain, respectively. In one embodiment, the composition of the at least one metal source/drain 107 may be selected to shift and/or lower the threshold voltage of the CNT device. As depicted, a larger metal source/drain work function leads in general for a smaller Schottky barrier height. Thus, by choosing the composition of the metal source/drain, the Schottky barrier height may be adjusted according to the particular application.

As shown in FIG. 2, for the same gate voltage V_{G} and drain voltage V_{DS}, metallic source/drains that comprise a larger work function Φₘ may lead to a smaller Schottky barrier height Φ_{b}, which may then lead to a larger thermionic emission current. The tunnel barriers (as are well known in the art) are also thinner for metallic source/drains that comprise a larger Φₘ, which leads to larger tunneling current. Therefore, at the same V_{G} and V_{DS}, source/drains with larger Φₘ metals lead to larger current, implying a lower threshold voltage V_{T}.

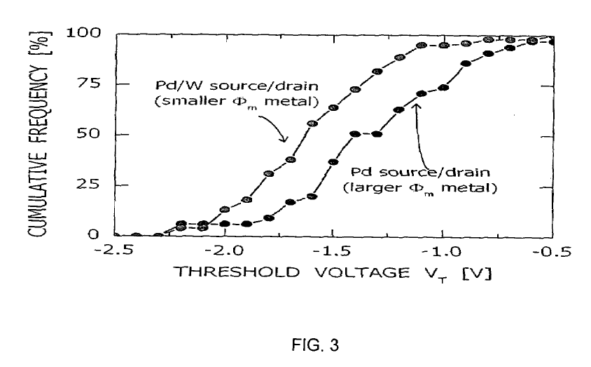

FIG. 3 depicts a cumulative frequency plot of the threshold voltage V_{T} of a CNT FET with palladium and Palladium/tungsten alloy source/drains, according to one embodiment. In one embodiment, as depicted in FIG. 3, CNT FETs utilizing palladium (Pd) contacts may comprise about a 250 mV lower V_{T} than those utilizing palladium/tungsten (Pd/W) contacts, thus demonstrating that CNT FETs with larger Φₘ metal source/drains may have a lower V_{T}.

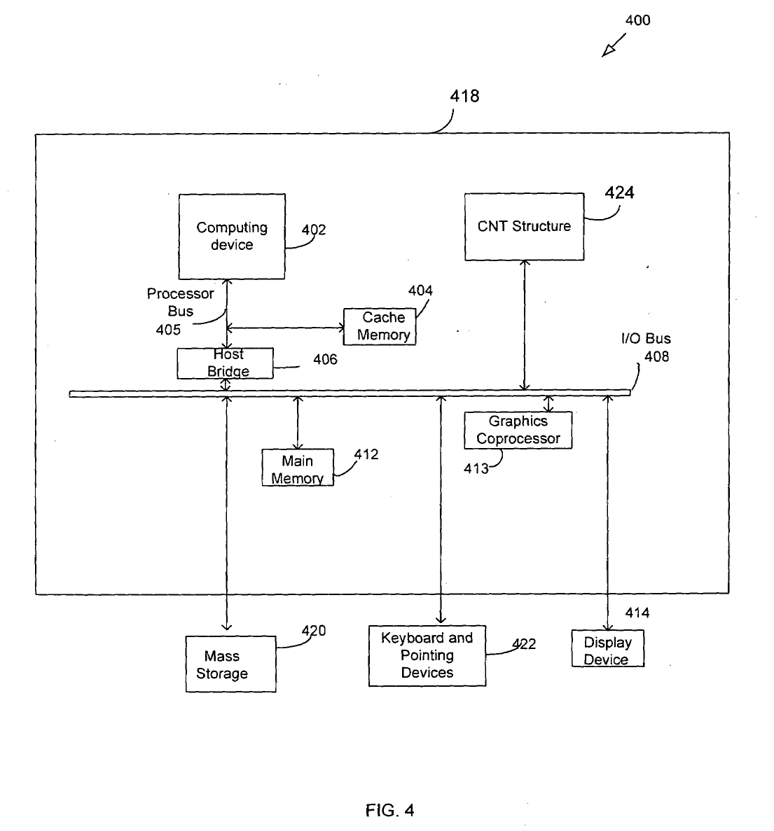

FIG. 4 is a diagram illustrating an exemplary system 400 capable of being operated with methods for fabricating a microelectronic structure, such as the CNT structure of FIG. 1e, for example. It will be understood that the present embodiment is but one of many possible systems in which the substrate core structures of the present invention may be used.

In the system 400, the CNT structure 424 may be communicatively coupled to a printed circuit board (PCB) 418 by way of an I/O bus 408. The communicative coupling of the CNT structure 424 may be established by physical means, such as through the use of a package and/or a socket connection to mount the CNT structure 424 to the PCB 418 (for example by the use of a chip package, interposer and/or a land grid array socket). The CNT structure 424 may also be communicatively coupled to the PCB 418 through various wireless means (for example, without the use of a physical connection to the PCB), as are well known in the art.

The system 400 may include a computing device 402, such as a processor, and a cache memory 404 communicatively coupled to each other through a processor bus 405. The processor bus 405 and the I/O bus 408 may be bridged by a host bridge 406. Communicatively coupled to the I/O bus 408 and also to the CNT structure 424 may be a main memory 412. Examples of the main memory 412 may include, but are not limited to, static random access memory (SRAM) and/or dynamic random access memory (DRAM), and/or some other state preserving mediums. The system 400 may also include a graphics coprocessor 413, however incorporation of the graphics coprocessor 413 into the system 400 is not necessary to the operation of the system 400. Coupled to the I/O bus 408 may also, for example, be a display device 414, a mass storage device 420, and keyboard and pointing devices 422.

These elements perform their conventional functions well known in the art. In particular, mass storage 420 may be used to provide long-term storage for the executable instructions for a method for forming CNT structures in accordance with embodiments of the present invention, whereas main memory 412 may be used to store on a shorter term basis the executable instructions of a method for forming CNT structures in accordance with embodiments of the present invention during execution by computing device 402. In addition, the instructions may be stored, or otherwise associated with, machine accessible mediums communicatively coupled with the system, such as compact disk read only memories (CD-ROMs), digital versatile disks (DVDs), and floppy disks, carrier waves, and/or other propagated signals, for example. In one embodiment, main memory 412 may supply the computing device 402 (which may be a processor, for example) with the executable instructions for execution.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices, such as a FET, are well known in the art. Therefore, it is appreciated that the Figures provided herein illustrate only portions of an exemplary microelectronic device that pertains to the practice of the present invention. Thus the present invention is not limited to the structures described herein.

1. A method of forming a device comprising:
forming at least one metal source/drain on a gate dielectric, wherein the at least one metal source/drain region is adjacent to a channel region, and wherein the channel region comprises at least one CNT.

2. The method of claim 1 wherein the at least one metal source/drain comprises a targeted work function to set a threshold voltage of the device.

3. The method of claim 2 wherein the targeted work function is selected to lower the threshold voltage.

4. The method of claim 1 wherein the gate dielectric is disposed on a backside gate.

5. The method of claim 1 wherein forming the at least one metal source/drain comprises forming a conductive material and then patterning the conductive material to form at least one metal source/drain.

6. The method of claim 5 wherein forming the conductive material comprises forming a layer of at least one of palladium and tungsten, and combinations thereof.

7. The method of claim 5 wherein forming the conductive material comprises forming a conductive layer that comprises a thickness between about 500 to about 2,000 angstroms.

8. The method of claim 1 wherein forming the device comprises forming a p channel FET.

9. The method of claim 1 wherein the at least one CNT comprises a at least one semiconducting CNT.

10. A method of forming a CNT device comprising;
forming a conductive material on a gate dielectric, wherein the gate dielectric is disposed on a backside gate;
patterning the conductive material into at least one metal source/drain; and
forming a channel region between the at least one metal source/drain,
wherein the channel region comprises at least one CNT.

11. The method of claim 10 wherein forming the conductive material further comprises wherein the conductive material comprises a targeted work function to set a threshold voltage of the CNT device.

12. The method of claim 10 wherein forming the conductive material further comprises wherein the composition of the conductive material is selected to shift a threshold voltage of the CNT device.

13. The method of claim 12 wherein the composition of the conductive material is selected comprises selecting a conductive material composition that comprises a work function that lowers the threshold voltage.

14. A structure comprising:
at least one metal source/drain disposed on a gate dielectric; and
a channel region between the at least one metal source/drain, wherein the channel region comprises at least one CNT.

15. The structure of claim 14 wherein the gate dielectric is disposed on a backside gate.

16. The structure of claim 14 wherein the backside gate comprises a p doped substrate.

17. The structure of claim 14 wherein the structure comprises a CNT FET.

18. The structure of claim 14 wherein the at least one metal source/drain comprises a work function capable of setting a voltage threshold of the CNT FET.

19. The structure of claim 14 wherein the at least one metal source/drain comprises at least one of palladium and tungsten.

20. The structure of claim 14 wherein the at least one metal source/drain comprises a thickness between about 500 and about 2,000 angstroms.

21. The structure of claim 14 wherein the at least one CNT comprises a at least one semiconducting CNT.

22. The structure of claim 14 wherein the gate dielectric comprises a dielectric constant greater than about 10.

23. A system comprising:
a CNT device comprising:
at least one metal source/drain disposed on a gate dielectric;
a channel region between and coupled to the at least one metal source/drain region, wherein the channel region comprises at least one CNT;
a bus communicatively coupled to the CNT device; and
a DRAM communicatively coupled to the bus.

24. The system of claim 23 wherein the gate dielectric is disposed on a backside gate.

25. The system of claim 23 wherein the at least one metal source/drain comprises a work function capable of setting a voltage threshold of the CNT device.

26. (canceled)
